(19) United States
(12) Patent Application Publication
(10) Pub. No.: US 2018/0102759 A1
(43) Pub. Date: Apr. 12, 2018

(54) ELASTIC WAVE DEVICE

(71) Applicant: Murata Manufacturing Co., Ltd., Nagaokakyo-shi (JP)

(72) Inventors: Hiroyuki NISHI, Nagaokakyo-shi (JP); Kazushi WATANABE, Nagaokakyo-shi (JP)

(21) Appl. No.: 15/835,490

(22) Filed: Dec. 8, 2017

Related U.S. Application Data
(63) Continuation of application No. PCT/JP2016/069630, filed on Jul. 1, 2016.

(30) Foreign Application Priority Data
Aug. 25, 2015 (JP) 2015-165531

(51) Int. Cl. H03H 9/10; H03H 9/02; H03H 9/05; H03H 9/145; H03H 9/25; H03H 9/72; H01L 23/544

(52) U.S. Cl. CPC H03H 9/1085; H03H 9/02559; H03H 9/059; H01L 2223/54406; H03H 9/25; H03H 9/725; H01L 23/544; H03H 9/14544

(57) ABSTRACT

An elastic wave device includes a sealing member sealing first and second elastic wave elements mounted on the mounting surface and including first and second surfaces, an impression being provided on the second surface. The first elastic wave element includes a first piezoelectric substrate made of LiNbO₃, and the second elastic wave element includes a second piezoelectric substrate made of LiNbO₃ or LiTaO₃. The thickness of the first piezoelectric substrate is larger than the thickness of the second piezoelectric substrate. When a side of the second surface of the sealing member is defined as an upper side and a side of the first surface of the sealing member is defined as a lower side, the thickness of the sealing member located above the first piezoelectric substrate is smaller than the thickness of the sealing member located above the second piezoelectric substrate. The first piezoelectric substrate and the impression do not overlap each other in a plan view from the second surface.

### CROSS REFERENCE TO RELATED APPLICATIONS

This application claims the benefit of priority to Japanese Patent Application No. 2015-165531 filed on Aug. 25, 2015 and is a Continuation Application of PCT Application No. PCT/JP2016/069630 filed on Jul. 1, 2016. The entire contents of each application are hereby incorporated herein by reference.

### BACKGROUND OF THE INVENTION

### 1. Field of the Invention

The present invention relates to an elastic wave device in which an impression is provided on a sealing member.

### 2. Description of the Related Art

An elastic wave device has been widely used in a cellular phone and other devices. For example, Japanese Unexamined Patent Application Publication No. 2011-199810 discloses an elastic wave device in which a bandpass filter chip for reception and a bandpass filter chip for transmission are mounted on a wiring board. The bandpass filter chip for transmission preferably includes a piezoelectric substrate formed of LiNbO₃. The bandpass filter chip for reception preferably includes a piezoelectric substrate formed of LiTaO₃. The thickness of the piezoelectric substrate of the bandpass filter chip for transmission is larger than the thickness of the piezoelectric substrate of the bandpass filter chip for reception. The bandpass filter chip for reception and the bandpass filter chip for transmission are covered with a sealing member.

In Japanese Unexamined Patent Application Publication No. 2011-199810, the thickness of the sealing member located above the bandpass filter chip for transmission is small. In an electronic component, for marking, an impression is often formed by providing a groove on a sealing member by application of laser light or other suitable mechanism. Since the sealing member above the bandpass filter chip for transmission is thin, an impression defect occurs in some cases. In the case of increasing the thickness of the sealing member, it is only necessary to decrease the thickness of the piezoelectric substrate made of LiNbO₃. However, since the strength of LiNbO₃ is low, when the thickness decreases, a breakage or other damage easily occurs. Thus, the reliability is impaired in some cases. On the other hand, when the thickness of the piezoelectric substrate made of LiNbO₃ is increased, it is difficult to decrease the height of the elastic wave device.

### SUMMARY OF THE INVENTION

Preferred embodiments of the present invention provide elastic wave devices that achieve improved reliability and decreased height.

According to a preferred embodiment of the present invention, an elastic wave device includes a mounting substrate including a mounting surface; a plurality of elastic wave elements mounted on the mounting surface of the mounting substrate; and a sealing member provided on the mounting surface of the mounting substrate, sealing the plurality of elastic wave elements, and including a first surface located at a side of the mounting substrate and a second surface opposing the first surface, wherein an impression is provided on the second surface, the plurality of elastic wave elements include first and second elastic wave elements, the first elastic wave element includes a first piezoelectric substrate including one surface opposing the mounting substrate and on which a first electrode is provided and another surface opposing the one surface and located at a side of the second surface, the first piezoelectric substrate is made of LiNbO₃, the second elastic wave element includes a second piezoelectric substrate including one surface opposing the mounting substrate and on which a second electrode is provided and another surface opposing the one surface and located at the side of the second surface, the second piezoelectric substrate is made of one of LiNbO₃ and LiTaO₃, a thickness of the first piezoelectric substrate is larger than a thickness of the second piezoelectric substrate, when the second surface side of the sealing member is defined as an upper side and the first surface side of the sealing member is defined as a lower side, a thickness of a portion of the sealing member that is located above the first piezoelectric substrate is smaller than a thickness of a portion of the sealing member that is located above the second piezoelectric substrate, and the first piezoelectric substrate and the impression do not overlap each other in a plan view of the sealing member from the second surface.

According to a preferred embodiment of the present invention, an elastic wave device includes a mounting substrate including a mounting surface; a plurality of elastic wave elements mounted on the mounting surface of the mounting substrate; and a sealing member provided on the mounting surface of the mounting substrate, sealing the plurality of elastic wave elements, and including a first surface located at a side of the mounting substrate and a second surface opposing the first surface, wherein an impression is provided on the second surface, the plurality of elastic wave elements include first and second elastic wave elements, the first elastic wave element includes a first piezoelectric substrate including one surface opposing the mounting substrate and on which an electrode is provided and another surface opposing the one surface and located at the second surface side, the first piezoelectric substrate is made of LiNbO₃, the second elastic wave element includes a second piezoelectric substrate including one surface opposing the mounting substrate and on which an electrode is provided and another surface opposing the one surface and located at the second surface side, the second piezoelectric substrate is made of one of LiNbO₃ and LiTaO₃, a thickness of the first piezoelectric substrate is larger than a thickness of the second piezoelectric substrate, when the second surface side of the sealing member is defined as an upper side and the first surface side of the sealing member is defined as a lower side, a thickness of a portion of the sealing member that is located above the first piezoelectric substrate is smaller than a thickness of a portion of the sealing member that is located above the second piezoelectric substrate, and in a plan view of the sealing member from the second surface, an area of a portion where the first piezoelectric substrate and the impression overlap each other is smaller than an area of a portion where the second piezoelectric substrate and the impression overlap each other.

According to a preferred embodiment of the present invention, an elastic wave device includes a plurality of the second elastic wave elements.

According to a preferred embodiment of the present invention, in an elastic wave device, the mounting surface of the mounting substrate includes a first side and a second side connected to the first side, and at least the two second elastic wave elements are disposed adjacent to each other along a direction in which one of the first and second sides extends. In this case, it is possible to increase the flexibility in the shape of the impression.

According to a preferred embodiment of the present invention, in an elastic wave device, the second piezoelectric substrate is made of LiTaO₃. In this case, since the strength of LiTaO₃ is higher than the strength of LiNbO₃, it is possible to decrease the thickness of the second piezoelectric substrate. Thus, it is possible to further increase the thickness of the sealing member located above the second piezoelectric substrate. Therefore, even when the impression is provided on the sealing member, it is possible to more reliably seal the first and second elastic wave elements.

According to a preferred embodiment of the present invention, in an elastic wave device, in a plan view of the mounting surface of the mounting substrate, in a sum of areas of the first and second piezoelectric substrates, a proportion of the area of the second piezoelectric substrate is higher than a proportion of the area of the first piezoelectric substrate. In this case, it is possible to increase the flexibility in the position at which the impression is provided, and it is possible to sufficiently seal the first and second elastic wave elements.

According to a preferred embodiment of the present invention, in an elastic wave device, in a plan view of the mounting surface of the mounting substrate, a sum of areas of the first and second piezoelectric substrates is not less than about 58% of a total area of the mounting surface of the mounting substrate. In this case, it is possible to suitably use preferred embodiments of the present invention.

According to a preferred embodiment of the present invention, in an elastic wave device, a first electrode land is provided on the first piezoelectric substrate, the first elastic wave element is mounted on the mounting substrate with a conductive joining material joined to the first electrode land and interposed therebetween, a second electrode land is provided on the second piezoelectric substrate, and the second elastic wave element is mounted on the mounting substrate with a conductive joining material joined to the second electrode land and interposed therebetween.

According to a preferred embodiment of the present invention, in an elastic wave device, the first piezoelectric substrate includes a first electrode surface, the second piezoelectric substrate includes a second electrode surface, the first elastic wave element includes a first interdigital transducer electrode provided on the first electrode surface, a first support member provided on the first electrode surface and surrounding the first interdigital transducer electrode in a plan view from the first electrode surface, a first cover member provided on the first support member, and a first under-bump metal layer penetrating the first cover member and the first support member, the first interdigital transducer electrode is sealed by the first piezoelectric substrate, the first support member, and the first cover member, a conductive joining material is joined to the first under-bump metal layer, the second elastic wave element includes a second interdigital transducer electrode provided on the second electrode surface, a second support member provided on the second electrode surface and surrounding the second interdigital transducer electrode in a plan view from the second electrode surface, a second cover member provided on the second support member, and a second under-bump metal layer penetrating the second cover member and the second support member, the second interdigital transducer electrode is sealed by the second piezoelectric substrate, the second support member, and the second cover member, and a conductive joining material is joined to the second under-bump metal layer.

According to various preferred embodiments of the present invention, it is possible to improve the reliability of elastic wave devices and to decrease the heights of the elastic wave devices.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1A is a plan view of an elastic wave device according to a first preferred embodiment of the present invention, and FIG. 1B is a cross-sectional view taken along the line A-A in FIG. 1A.

FIG. 2 is a plan view of an elastic wave device according to a modification of the first preferred embodiment of the present invention.

FIG. 3 is a plan view of an elastic wave device according to a second preferred embodiment of the present invention.

FIG. 4 is a plan view of an elastic wave device according to a third preferred embodiment of the present invention.

FIG. 5 is a plan view of an elastic wave device according to a fourth preferred embodiment of the present invention.

FIG. 6 is a front cross-sectional view of an elastic wave device according to a fifth preferred embodiment of the present invention.

### DETAILED DESCRIPTION OF THE PREFERRED EMBODIMENTS

Hereinafter, the present invention will be clarified by describing specific preferred embodiments of the present invention with reference to the drawings.

It should be noted that each preferred embodiment described in the present specification is illustrative and the components may be partially replaced or combined between different preferred embodiments.

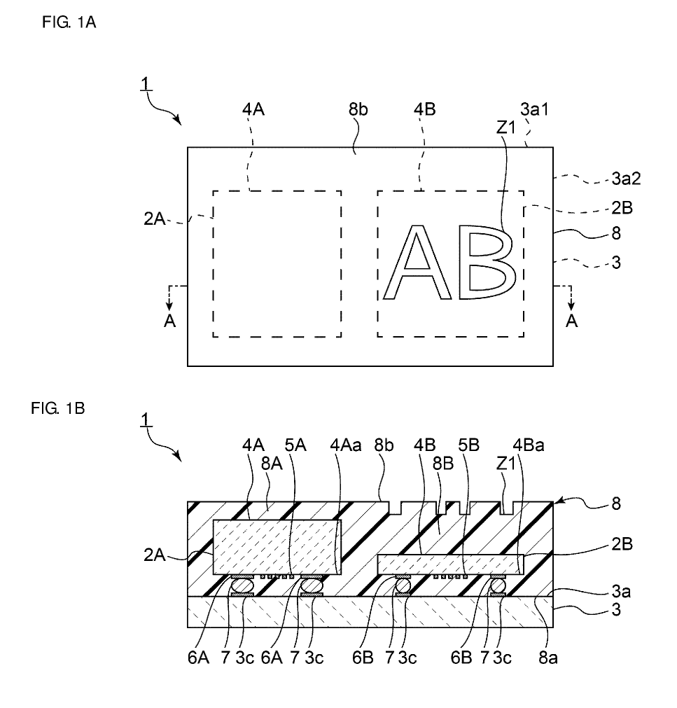

FIG. 1A is a plan view of an elastic wave device according to a first preferred embodiment of the present invention. FIG. 1B is a cross-sectional view taken along the line A-A in FIG. 1A.

As shown in FIG. 1B, an elastic wave device 1 includes a mounting substrate 3. The mounting substrate 3 includes a mounting surface 3a. The mounting substrate 3 is preferably made of an appropriate ceramic material, resin material, or other suitable material, for example.

First and second elastic wave elements 2A and 2B are mounted on the mounting surface 3a. In the present preferred embodiment, the elastic wave device 1 is preferably a duplexer, for example. The first elastic wave element 2A is a transmitting filter chip, and the second elastic wave element 2B is a receiving filter chip.

The first elastic wave element 2A includes a first piezoelectric substrate 4A opposing the mounting substrate 3. The first piezoelectric substrate 4A includes, as one principal surface, a first electrode surface 4Aa opposing the mounting substrate 3. The first piezoelectric substrate 4A also includes another principal surface opposing the first electrode surface 4Aa. The first piezoelectric substrate 4A is preferably made of LiNbO₃, for example.

A plurality of interdigital transducer electrodes including a first interdigital transducer electrode 5A, as a first electrode, are provided on the first electrode surface 4Aa. The plurality of interdigital transducer electrodes including the first interdigital transducer electrode 5A define a transmitting filter. A first electrode land 6A connected electrically to the first interdigital transducer electrode 5A is also provided on the first electrode surface 4Aa.

A conductive joining material 7 is joined to the first electrode land 6A. The conductive joining material 7 is preferably made of a solder, conductive paste, or other suitable joining material, for example. The first elastic wave element 2A is mounted on the mounting surface 3a of the mounting substrate 3 with the conductive joining material 7 interposed therebetween. More specifically, a terminal electrode 3c is provided on the mounting surface 3a. The conductive joining material 7 connects the terminal electrode 3c and the first electrode land 6A. The first interdigital transducer electrode 5A is electrically connected to the outside via the first electrode land 6A, the conductive joining material 7, and the terminal electrode 3c.

The second elastic wave element 2B includes a second piezoelectric substrate 4B opposing the mounting substrate 3. The second piezoelectric substrate 4B includes, as one principal surface, a second electrode surface 4Ba opposing the mounting substrate 3. The second piezoelectric substrate 4B also includes another principal surface opposing the second electrode surface 4Ba. The thickness of the second piezoelectric substrate 4B is preferably smaller than the thickness of the first piezoelectric substrate 4A. The second piezoelectric substrate 4B is preferably made of LiTaO₃, for example. The second piezoelectric substrate may also be made of LiNbO₃.

A plurality of interdigital transducer electrodes including a second interdigital transducer electrode 5B, as a second electrode, are provided on the second electrode surface 4Ba. The plurality of interdigital transducer electrodes including the second interdigital transducer electrode 5B define a receiving filter. A second electrode land 6B connected electrically to the second interdigital transducer electrode 5B is also provided on the second electrode surface 4Ba.

Similarly to the first elastic wave element 2A, the second elastic wave element 2B is also mounted on the mounting surface 3a of the mounting substrate 3 with a conductive joining material 7 joined to the second electrode land 6B and interposed therebetween. More specifically, the conductive joining material 7 connects the second electrode land 6B and the terminal electrode 3c. The second interdigital transducer electrode 5B is electrically connected to the outside via the second electrode land 6B, the conductive joining material 7, and the terminal electrode 3c.

Each of the first and second interdigital transducer electrodes 5A and 5B and the first and second electrode lands 6A and 6B is made of an appropriate metal.

The first and second interdigital transducer electrodes 5A and 5B may be provided by, for example, sputtering, CVD, or other suitable method. The first and second electrode lands 6A and 6B also may be provided by, for example, sputtering, CVD, or other suitable method.

A sealing member 8 is provided on the mounting surface 3a. The sealing member 8 seals the first and second elastic wave elements 2A and 2B. The sealing member 8 includes a first surface 8a located at the mounting substrate 3 side. The sealing member 8 also includes a second surface 8b opposing the first surface 8a. The sealing member 8 preferably includes a resin, such as an epoxy resin, for example, as a main component.

Here, the other principal surface of the first piezoelectric substrate 4A is located at the second surface 8b side in the first elastic wave element 2A. The other principal surface of the second piezoelectric substrate 4B is also located at the second surface 8b side in the second elastic wave element 2B. That is, the first piezoelectric substrate 4A is located closest to the second surface 8b among the components of the first elastic wave element 2A. The second piezoelectric substrate 4B is also located closest to the second surface 8b among the components of the second elastic wave element 2B.

In a plan view from the second surface 8b, the area of the second piezoelectric substrate 4B is preferably larger than the area of the first piezoelectric substrate 4A.

Here, the second surface 8b side of the sealing member 8 shown in FIG. 1B is defined as an upper side, and the first surface 8a side thereof is defined as a lower side. In this case, the sealing member 8 includes a first portion 8A located above the first piezoelectric substrate 4A. The sealing member 8 also has a second portion 8B located above the second piezoelectric substrate 4B.

As shown in FIG. 1A, an impression Z1 is provided on the second surface 8b by grooves having a predetermined depth. The depth of the grooves of the impression Z1 is preferably not less than about 20 μm and not greater than about 40 μm, for example. The pattern of the impression Z1 is not particularly limited. The impression Z1 is formed by the sealing member 8 being partially removed by, for example, application of laser light or other suitable mechanism. The grooves of the impression Z1 are provided by application of laser light having a certain application intensity, and are desirably grooves having a uniform depth and a uniform width. In the present preferred embodiment, the recognizability of the impression Z1 is improved, for example, by providing the impression Z1 such that the width of the grooves is about 20±3 μm, the depth of the grooved is about 40±3 μm, and the depth dimension of the grooves is larger than the width dimension of the grooves.

The present preferred embodiment preferably has the following configurations: 1) the thickness of the first piezoelectric substrate 4A is larger than the thickness of the second piezoelectric substrate 4B; 2) the thickness of the first portion 8A of the sealing member 8 is smaller than the thickness of the second portion 8B of the sealing member 8; and 3) the first piezoelectric substrate 4A and the impression Z1 do not overlap each other in a plan view from the second surface 8b. Accordingly, it is possible to improve the reliability of the elastic wave device 1, in which the impression Z1 is provided on the sealing member 8, and to decrease the height of the elastic wave device 1. This will be described in more detail below.

In the present preferred embodiment, the thickness of the first piezoelectric substrate 4A, which is preferably made of LiNbO₃, is larger than the thickness of the second piezoelectric substrate 4B, which is preferably made of LiTaO₃. Thus, the strength of the first piezoelectric substrate 4A is increased. Therefore, it is possible to improve the reliability of the elastic wave device 1.

Since the impression Z1 is not provided above the first piezoelectric substrate 4A, it is possible to further decrease the thickness of the first portion 8A of the sealing member 8. Thus, a decrease in the height of the elastic wave device 1 is achieved.

For example, in the elastic wave device 1, the thickness of the first portion 8A of the sealing member 8 may be thin to such an extent that it is impossible to form the impression Z1 thereon. In this case, it is possible to achieve a further decrease in the height.

The impression Z1 is provided on the second portion 8B having a large thickness. Thus, in a process of producing the elastic wave device 1, it is possible to reliably form the impression Z1. In addition, it is possible to reliably seal the first and second elastic wave elements 2A and 2B. Thus, it is possible to sufficiently improve the reliability.

The first and second portions 8A and 8B of the sealing member 8 are portions provided on the first and second piezoelectric substrates 4A and 4B. Thus, at the first and second portions 8A and 8B, the second surface 8b is flat or substantially flat. In the present preferred embodiment, the impression Z1 is provided on only a portion of the sealing member 8 that overlaps the second piezoelectric substrate 4B in a plan view from the second surface 8b of the sealing member 8. Thus, variations in the thickness, tilt, and other parameters of the sealing member 8 are small in the portion on which the impression Z1 is provided. Therefore, in the process of producing the elastic wave device 1, it is possible to easily and reliably form the impression Z1.

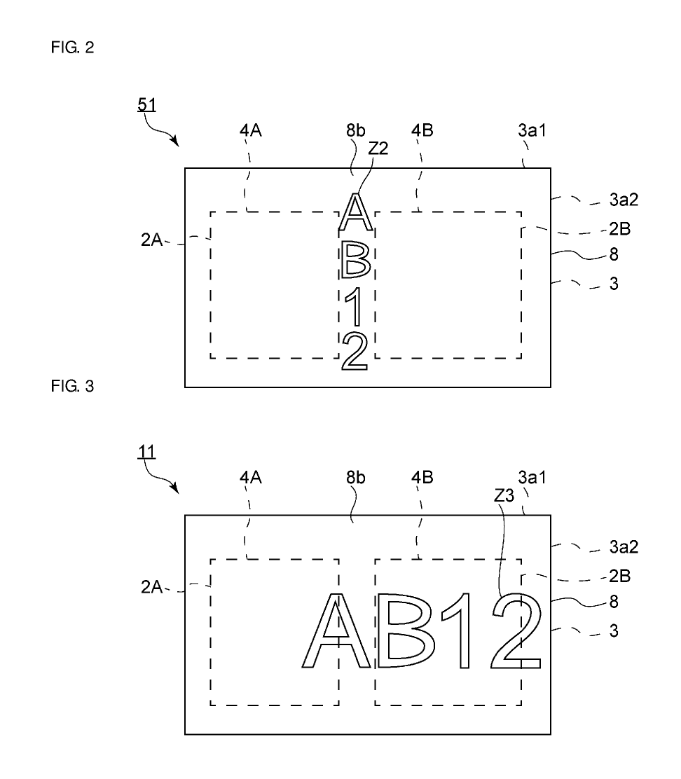

As in an elastic wave device 51 of a modification shown in FIG. 2, an impression Z2 may preferably be provided in only a region above a portion in which the first and second piezoelectric substrates 4A and 4B are not located in a plan view from the second surface 8b of the sealing member 8. As a matter of course, an impression is preferably provided in not only the region above the portion in which the first and second piezoelectric substrates are not located, but also above a portion in which the second piezoelectric substrate is located. Accordingly, the elastic wave device is unlikely to be broken, for example, when pressure is applied to the elastic wave device.

More preferably, in the plan view, the area of a portion in which the second piezoelectric substrate and the impression overlap each other is larger than the area of a portion in which the impression and the portion in which the first and second piezoelectric substrates are not located overlap each other. Accordingly, it is possible to easily form the impression. Furthermore, the elastic wave device is even less likely to be broken.

Even more preferably, as in the first preferred embodiment shown in FIGS. 1A and 1B, the impression and the portion in which the first and second piezoelectric substrates 4A and 4B are not located do not overlap each other in a plan view from the second surface 8b.

As described above, the second piezoelectric substrate may be made of LiNbO₃. In the present preferred embodiment, the second piezoelectric substrate 4B is preferably made of LiTaO₃, which has higher strength than LiNbO₃. Accordingly, breakage of the second piezoelectric substrate 4B is unlikely to occur even when the thickness of the second piezoelectric substrate 4B is decreased. Thus, it is possible to further increase the thickness of the second portion 8B of the sealing member 8. Therefore, even when the impression Z1 is provided on the sealing member 8, it is possible to more reliably seal the first and second elastic wave elements 2A and 2B.

In the present preferred embodiment, the area of the second piezoelectric substrate 4B is preferably larger than the area of the first piezoelectric substrate 4A. Thus, the area of the thick portion of the sealing member 8 is large. Therefore, it is possible to increase the flexibility in the position at which the impression Z1 is provided, and it is possible to sufficiently seal the first and second elastic wave elements 2A and 2B. In the present specification, the area is a planar area in a plan view from the second surface 8b.

FIG. 3 is a plan view of an elastic wave device according to a second preferred embodiment of the present invention.

The elastic wave device 11 is different from the first preferred embodiment in that an impression Z3 is also provided on a portion of the sealing member 8 that does not overlap the second piezoelectric substrate 4B in a plan view from the second surface 8b of the sealing member 8. Except for the above, the elastic wave device 11 preferably has the same or substantially the same configuration as the elastic wave device 1 of the first preferred embodiment.

More specifically, in the present preferred embodiment, the first and second piezoelectric substrates 4A and 4B and the impression Z3 overlap each other in a plan view from the second surface 8b. The area of a portion where the first piezoelectric substrate 4A and the impression Z3 overlap each other is preferably smaller than the area of a portion where the second piezoelectric substrate 4B and the impression Z3 overlap each other. Thus, it is possible to sufficiently seal the first and second elastic wave elements 2A and 2B.

Preferably, the thickness of the first portion 8A of the sealing member 8 is not less than about 20 μm, for example. Thus, it is possible to reliably provide the impression. In order to achieve a decrease in the height of the elastic wave device 11, the thickness of the first portion 8A is preferably not greater than about 100 μm, for example.

As shown in FIG. 3, in a plan view from the second surface 8b, the impression Z3 may preferably also overlap the portion in which the first and second piezoelectric substrates 4A and 4B are not located.

As in the present preferred embodiment, the sum of the areas of the first and second piezoelectric substrates 4A and 4B in a plan view of the mounting surface 3a of the mounting substrate 3 is preferably not less than about 58%, for example, of the entire area of the mounting surface 3a of the mounting substrate 3. In this case, it is possible to suitably use preferred embodiments of the present invention.

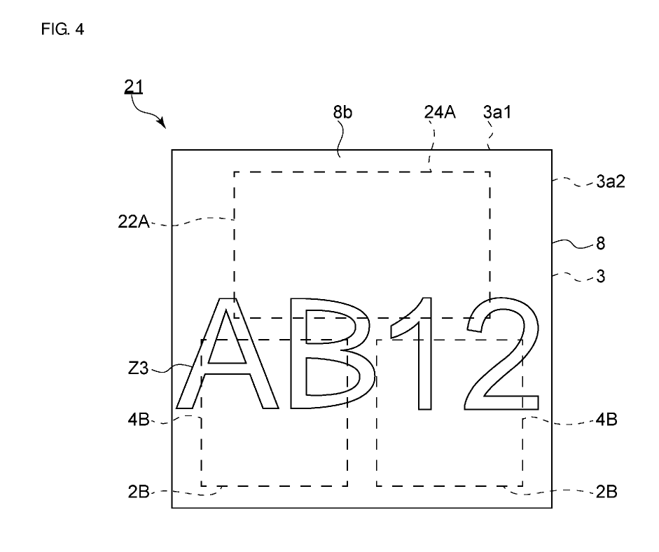

FIG. 4 is a plan view of an elastic wave device according to a third preferred embodiment.

The elastic wave device 21 is different from the second preferred embodiment in that a plurality of second elastic wave elements 2B are included and the area of a first piezoelectric substrate 24A is preferably larger than the area of each second piezoelectric substrate 4B. Except for the above, the elastic wave device 21 preferably has the same or substantially the same configuration as the elastic wave device 11 of the second preferred embodiment.

The mounting surface of the mounting substrate 3 includes a first side 3a1 and a second side 3a2 connected to the first side 3a1. Two second elastic wave elements 2B are disposed adjacent to each other along the direction in which the first side 3a1 extends. Accordingly, it is possible to increase the flexibility in the shape of the impression Z3, and it is possible to sufficiently seal first and second elastic wave elements 22A and 2B.

The area of the first piezoelectric substrate 24A may preferably be larger than the area of each second piezoelectric substrate 4B. In the present preferred embodiment, in the sum of the areas of the first and second piezoelectric substrates 24A and 4B, the proportion of the areas of the second piezoelectric substrates 4B is preferably higher than the proportion of the area of the first piezoelectric substrate 24A. Accordingly, it is also possible to increase the flexibility in the position at which the impression Z3 is provided.

FIG. 5 is a plan view of an elastic wave device according to a fourth preferred embodiment of the present invention.

The elastic wave device 31 is different from the second preferred embodiment in that a plurality of first elastic wave elements 2A and a plurality of second elastic wave elements 2B are preferably included. Except for the above, the elastic wave device 31 has the same or substantially the same configuration as the elastic wave device 11 of the second preferred embodiment.

More specifically, in the present preferred embodiment, two first elastic wave elements 2A and two second elastic wave elements 2B are preferably included, for example. The numbers of the first and second elastic wave elements are not particularly limited. In the present preferred embodiment as well, it is possible to achieve the same or similar advantageous effects as those of the second preferred embodiment.

The two second elastic wave elements 2B are disposed adjacent to each other along the direction in which the second side 3a2 extends. Thus, in the present preferred embodiment as well, similarly to the third preferred embodiment, it is possible to increase the flexibility in the shape of an impression Z4, and it is possible to sufficiently seal the first and second elastic wave elements 2A and 2B. As described above, at least the two second elastic wave elements only need to be disposed adjacent to each other, and the direction in which the two second elastic wave elements are adjacent to each other is not particularly limited.

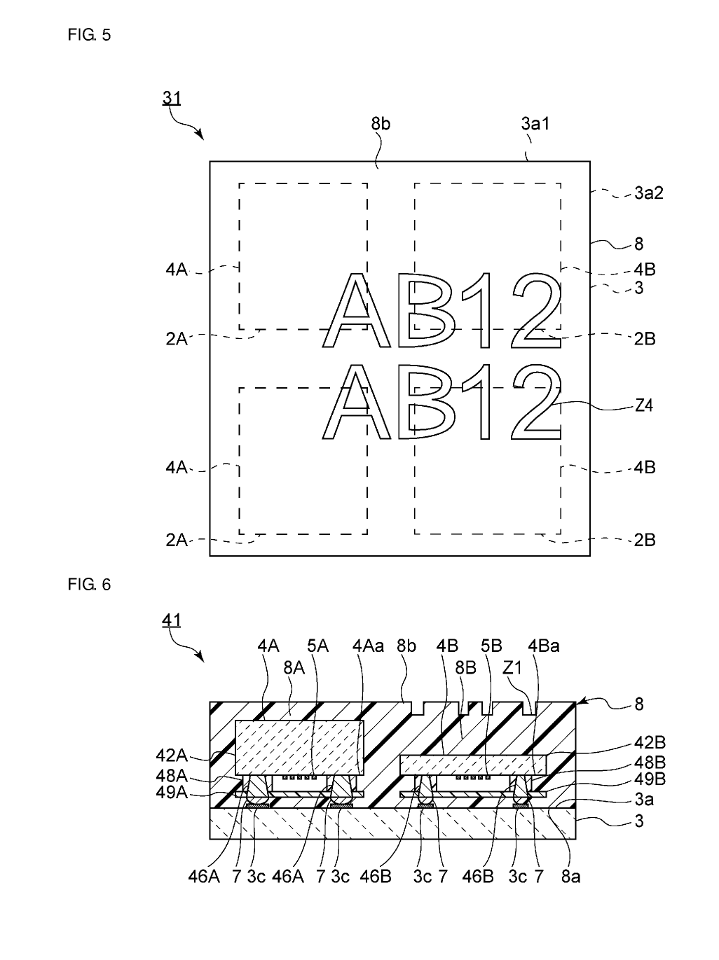

FIG. 6 is a front cross-sectional view of an elastic wave device according to a fifth preferred embodiment of the present invention.

The elastic wave device 41 is different from the first preferred embodiment in that first and second elastic wave elements 42A and 42B preferably have a WLP (Wafer Level Package) structure. Except for the above, the elastic wave device 41 has the same or substantially the same configuration as the elastic wave device 1 of the first preferred embodiment.

More specifically, the first elastic wave element 42A includes a first support member 48A provided on the first electrode surface 4Aa of the first piezoelectric substrate 4A. In a plan view from the first electrode surface 4Aa, the first support member 48A surrounds the first interdigital transducer electrode 5A. The first support member 48A is preferably made of an appropriate resin. The first support member 48A may be provided by, for example, photolithography or other suitable method.

A first cover member 49A is provided on the first support member 48A. The first piezoelectric substrate 4A, the first support member 48A, and the first cover member 49A seal the first interdigital transducer electrode 5A.

A first under-bump metal layer 46A penetrates the first cover member 49A and the first support member 48A. The first under-bump metal layer 46A is electrically connected to the first interdigital transducer electrode 5A. The conductive joining material 7 is joined to the first under-bump metal layer 46A. In the present preferred embodiment, the conductive joining material 7 is preferably made of solder or other suitable joining material, for example. The first elastic wave element 42A is mounted on the mounting substrate 3 with the conductive joining material 7 interposed therebetween. More specifically, the conductive joining material 7 connects the first under-bump metal layer 46A and the terminal electrode 3c on the mounting substrate 3. The first interdigital transducer electrode 5A is electrically connected to the outside via the first under-bump metal layer 46A, the conductive joining material 7, and the terminal electrode 3c.

The second elastic wave element 42B preferably also has the same or substantially the same configuration as the first elastic wave element 42A. More specifically, the second elastic wave element 42B includes a second support member 48B provided on the second electrode surface 4Ba of the second piezoelectric substrate 4B. In a plan view from the second electrode surface 4Ba, the second support member 48B surrounds the second interdigital transducer electrode 5B.

A second cover member 49B is provided on the second support member 48B. The second piezoelectric substrate 4B, the second support member 48B, and the second cover member 49B seal the second interdigital transducer electrode 5B.

A second under-bump metal layer 46B penetrates the second cover member 49B and the second support member 48B. The second under-bump metal layer 46B is electrically connected to the second interdigital transducer electrode 5B. The conductive joining material 7 is joined to the second under-bump metal layer 46B. The second elastic wave element 42B is mounted on the mounting substrate 3 with the conductive joining material 7 interposed therebetween. More specifically, the conductive joining material 7 connects the second under-bump metal layer 46B and the terminal electrode 3c on the mounting substrate 3. The second interdigital transducer electrode 5B is electrically connected to the outside via the second under-bump metal layer 46B and the conductive joining material 7.

In this case as well, similarly to the first preferred embodiment, it is possible to improve the reliability of the elastic wave device 41, and it is possible to decrease the height of the elastic wave device 41.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An elastic wave device comprising:
a mounting substrate including a mounting surface;
a plurality of elastic wave elements mounted on the mounting surface of the mounting substrate; and
a sealing member provided on the mounting surface of the mounting substrate, sealing the plurality of elastic wave elements, and including a first surface located at a side of the mounting substrate and a second surface opposing the first surface, an impression being provided on the second surface;
wherein
the plurality of elastic wave elements include first and second elastic wave elements;
the first elastic wave element includes a first piezoelectric substrate including one surface opposing the mounting substrate and on which a first electrode is provided and another surface opposing the one surface and located at a side of the second surface, the first piezoelectric substrate being made of LiNbO₃;
the second elastic wave element includes a second piezoelectric substrate including one surface opposing the mounting substrate and on which a second electrode is provided and another surface opposing the one surface and located at the side of the second surface, the second piezoelectric substrate being made of one of LiNbO₃ and LiTaO₃;
a thickness of the first piezoelectric substrate is larger than a thickness of the second piezoelectric substrate;
when the side of the second surface of the sealing member is defined as an upper side and a side of the first surface of the sealing member is defined as a lower side, a thickness of a portion of the sealing member that is located above the first piezoelectric substrate is smaller than a thickness of a portion of the sealing member that is located above the second piezoelectric substrate; and
the first piezoelectric substrate and the impression do not overlap each other in a plan view of the sealing member from the second surface.

2. The elastic wave device according to claim 1, wherein the elastic wave device includes a plurality of the second elastic wave elements.

3. The elastic wave device according to claim 2, wherein the mounting surface of the mounting substrate includes a first side and a second side connected to the first side, and at least the plurality of second elastic wave elements are disposed adjacent to each other along a direction in which one of the first and second sides extends.

4. The elastic wave device according to claim 1, wherein the second piezoelectric substrate is made of LiTaO₃.

5. The elastic wave device according to claim 1, wherein in a plan view of the mounting surface of the mounting substrate, in a sum of areas of the first and second piezoelectric substrates, a proportion of the area of the second piezoelectric substrate is higher than a proportion of the area of the first piezoelectric substrate.

6. The elastic wave device according to claim 1, wherein in a plan view of the mounting surface of the mounting substrate, a sum of areas of the first and second piezoelectric substrates is not less than about 58% of a total area of the mounting surface of the mounting substrate.

7. The elastic wave device according to claim 1, wherein
a first electrode land is provided on the first piezoelectric substrate, and the first elastic wave element is mounted on the mounting substrate with a conductive joining material joined to the first electrode land and interposed therebetween; and
a second electrode land is provided on the second piezoelectric substrate, and the second elastic wave element is mounted on the mounting substrate with a conductive joining material joined to the second electrode land and interposed therebetween.

8. The elastic wave device according to claim 1, wherein
the first piezoelectric substrate includes a first electrode surface, and the second piezoelectric substrate includes a second electrode surface;
the first elastic wave element includes a first interdigital transducer electrode provided on the first electrode surface, a first support member provided on the first electrode surface and surrounding the first interdigital transducer electrode in a plan view from the first electrode surface, a first cover member provided on the first support member, and a first under-bump metal layer penetrating the first cover member and the first support member, and the first interdigital transducer electrode is sealed by the first piezoelectric substrate, the first support member, and the first cover member;
a conductive joining material is joined to the first under-bump metal layer;
the second elastic wave element includes a second interdigital transducer electrode provided on the second electrode surface, a second support member provided on the second electrode surface and surrounding the second interdigital transducer electrode in a plan view from the second electrode surface, a second cover member provided on the second support member, and a second under-bump metal layer penetrating the second cover member and the second support member, and the second interdigital transducer electrode is sealed by the second piezoelectric substrate, the second support member, and the second cover member, and
another conductive joining material is joined to the second under-bump metal layer.

9. The elastic wave device according to claim 1, wherein the impression is defined by grooves.

10. The elastic wave device according to claim 9, wherein a depth of the grooves is not less than about 20 μm and not greater than about 40 μm.

11. An elastic wave device comprising:
a mounting substrate including a mounting surface;
a plurality of elastic wave elements mounted on the mounting surface of the mounting substrate; and
a sealing member provided on the mounting surface of the mounting substrate, sealing the plurality of elastic wave elements, and including a first surface located at a side of the mounting substrate and a second surface opposing the first surface, an impression being provided on the second surface;
wherein
the plurality of elastic wave elements include first and second elastic wave elements;
the first elastic wave element includes a first piezoelectric substrate including one surface opposing the mounting substrate and on which an electrode is provided and another surface opposing the one surface and located at a side of the second surface, the first piezoelectric substrate being made of LiNbO₃;
the second elastic wave element includes a second piezoelectric substrate including one surface opposing the mounting substrate and on which an electrode is provided and another surface opposing the one surface and located at the side of the second surface, the second piezoelectric substrate being made of one of LiNbO₃ and LiTaO₃;
a thickness of the first piezoelectric substrate is larger than a thickness of the second piezoelectric substrate;
when the side of the second surface of the sealing member is defined as an upper side and a side of the first surface of the sealing member is defined as a lower side, a thickness of a portion of the sealing member that is located above the first piezoelectric substrate is smaller than a thickness of a portion of the sealing member that is located above the second piezoelectric substrate; and
in a plan view of the sealing member from the second surface, an area of a portion where the first piezoelectric substrate and the impression overlap each other is smaller than an area of a portion where the second piezoelectric substrate and the impression overlap each other.

12. The elastic wave device according to claim 11, wherein the elastic wave device includes a plurality of the second elastic wave elements.

13. The elastic wave device according to claim 12, wherein the mounting surface of the mounting substrate includes a first side and a second side connected to the first side, and at least the plurality of second elastic wave elements are disposed adjacent to each other along a direction in which one of the first and second sides extends.

14. The elastic wave device according to claim 11, wherein the second piezoelectric substrate is made of LiTaO₃.

15. The elastic wave device according to claim 11, wherein in a plan view of the mounting surface of the mounting substrate, in a sum of areas of the first and second piezoelectric substrates, a proportion of the area of the second piezoelectric substrate is higher than a proportion of the area of the first piezoelectric substrate.

16. The elastic wave device according to claim 11, wherein in a plan view of the mounting surface of the mounting substrate, a sum of areas of the first and second piezoelectric substrates is not less than about 58% of a total area of the mounting surface of the mounting substrate.

17. The elastic wave device according to claim 11, wherein
a first electrode land is provided on the first piezoelectric substrate, and the first elastic wave element is mounted on the mounting substrate with a conductive joining material joined to the first electrode land and interposed therebetween; and
a second electrode land is provided on the second piezoelectric substrate, and the second elastic wave element is mounted on the mounting substrate with a conductive joining material joined to the second electrode land and interposed therebetween.

18. The elastic wave device according to claim 11, wherein
the first piezoelectric substrate includes a first electrode surface, and the second piezoelectric substrate includes a second electrode surface;
the first elastic wave element includes a first interdigital transducer electrode provided on the first electrode surface, a first support member provided on the first electrode surface and surrounding the first interdigital transducer electrode in a plan view from the first electrode surface, a first cover member provided on the first support member, and a first under-bump metal layer penetrating the first cover member and the first support member, and the first interdigital transducer electrode is sealed by the first piezoelectric substrate, the first support member, and the first cover member;
a conductive joining material is joined to the first under-bump metal layer;
the second elastic wave element includes a second interdigital transducer electrode provided on the second electrode surface, a second support member provided on the second electrode surface and surrounding the second interdigital transducer electrode in a plan view from the second electrode surface, a second cover member provided on the second support member, and a second under-bump metal layer penetrating the second cover member and the second support member, and the second interdigital transducer electrode is sealed by the second piezoelectric substrate, the second support member, and the second cover member, and
another conductive joining material is joined to the second under-bump metal layer.

19. The elastic wave device according to claim 11, wherein the impression is defined by grooves.

20. The elastic wave device according to claim 19, wherein a depth of the grooves is not less than about 20 μm and not greater than about 40 μm.
